(19) United States
(12) Patent Application Publication
(10) Pub. No.: US 2025/0326069 A1
(43) Pub. Date: Oct. 23, 2025

(54) THIN FILM FOR SEMICONDUCTOR LASER BONDING AND METHOD FOR PRODUCING SAME

(71) Applicant: CITIZEN FINEDEVICE CO., LTD., Yamanashi (JP)

(72) Inventors: Mitsunori Miyamoto, Yamanashi (JP); Toshihide Sekine, Yamanashi (JP)

(73) Assignee: CITIZEN FINEDEVICE CO., LTD., Yamanashi (JP)

(21) Appl. No.: 19/142,416

(22) PCT Filed: Aug. 14, 2024
(86) PCT No.: PCT/JP2024/028958

§ 371 Date: Jun. 23, 2025

(30) Foreign Application Priority Data
Aug. 25, 2023 (JP) 2023-137407

(51) Int. Cl. B23K 35/26; B23K 35/02; B32B 15/01; B32B 15/20; C22C 13/00; H01S 5/0237

(52) U.S. Cl. CPC B23K 35/262; B23K 35/0238; B32B 15/01; B32B 15/20; C22C 13/00; H01S 5/0237; B32B 2457/14

(57) ABSTRACT

A thin film for semiconductor laser bonding includes a solder layer that contains 7.2-14.0 wt % Au, 0.1-4.4 wt % Ag, and 0.1-10.1 wt % Cu with the remainder except unavoidable impurities being Sn.

### FIELD

The present disclosure relates to a thin film for semiconductor laser bonding and a method for producing the same.

### BACKGROUND

Various known techniques improve the performance of thin solder films used for mounting light-emitting devices such as laser diodes on submount substrates. For example, Non-Patent Document 1 (“Development of the low melting point Sn-based thin film solder possible to join with fluxless,” Sakamoto et al., Journal of the Japan Institute of Electronics Packaging, Vol. 14, No. 3, 2011, pp. 179-188) describes a thin solder film that does not require flux, which may degrade the performance of light-emitting elements. In the thin solder film described in Non-Patent Document 1, a Ag layer is disposed between a Sn layer and a Au layer, inhibiting the diffusion of Au contained in the Au layer into the Sn layer and reducing the occurrence of poor wetting and Kirkendall voids caused by surface oxidation.

Patent Document 1 (JP2007-288001A) describes a thin solder film in which a Ag layer and a Cu layer are disposed between three Sn layers, the Ag content is 5.5 wt % or less, the Cu content is 1.5 wt % or less, and the Sn content is 93.0 wt % or more. The thin solder film described in Patent Document 1 is bonded to a Au electrode to form a SnAgCuAu alloy, achieving a melting point of 250° C. or less.

### SUMMARY

The thin solder film described in Non-Patent Document 1 can reduce the occurrence of poor wetting and voids, and the thin solder film described in Patent Document 1 can achieve a melting point of 250° C. or less. However, there is a demand for thin films for semiconductor laser bonding that have higher performance and lower melting points.

The present disclosure solves such a problem and provides a thin film for semiconductor laser bonding that has high performance and a low melting point.

A thin film for semiconductor laser bonding of the present disclosure includes a solder layer that contains 7.2-14.0 wt % Au, 0.1-4.4 wt % Ag, and 0.1-10.1 wt % Cu with the remainder except unavoidable impurities being Sn.

In the thin film for semiconductor laser bonding of the present disclosure, a Cu layer made of Cu is preferably disposed all over one surface of the solder layer.

The thin film for semiconductor laser bonding of the present disclosure preferably contains 7.3-14.0 wt % Au.

The thin film for semiconductor laser bonding of the present disclosure preferably contains 0.1-4.4 wt % Ag and 0.1-6.7 wt % Cu.

The thin film for semiconductor laser bonding of the present disclosure preferably contains 0.1-10.1 wt % Cu and 0.1-3.1 wt % Ag.

The thin film for semiconductor laser bonding of the present disclosure preferably further includes a diffusion prevention layer containing Pt and disposed so as to face a surface of the solder layer on which the Cu is disposed.

In the thin film for semiconductor laser bonding of the present disclosure, the diffusion prevention layer preferably includes a Cr layer containing Cr and a Pt layer that contains Pt and that is disposed between the Cr layer and the solder layer.

A method for producing a thin film for semiconductor laser bonding of the present disclosure is a method for producing a thin film for semiconductor laser bonding including a solder layer that contains 7.2-14.0 wt % Au, 0.1-4.4 wt % Ag, and 0.1-10.1 wt % Cu with the remainder except unavoidable impurities being Sn. The method includes depositing a Cu layer, forming a Ag layer on the Cu layer, forming a Sn layer on the Ag layer, and forming a Au layer on the Sn layer.

The thin film for semiconductor laser bonding of the present disclosure has high performance and a low melting point.

### BRIEF DESCRIPTION OF DRAWINGS

FIG. 1 shows a thin film for semiconductor laser bonding of a first embodiment;

FIG. 2(a) shows the state of a reaction that occurs between Cu contained in a Cu layer and Sn contained in a Sn layer when the thin film for semiconductor laser bonding shown in FIG. 1 is heated; (b) shows photographs of a cross section of the thin film for semiconductor laser bonding shown in FIG. 1 before and after melting;

FIG. 3 is a Sn—Ag—Cu phase diagram;

FIG. 4 is a Au—Sn phase diagram;

FIG. 5(a) is a flowchart showing a method for producing the thin film for semiconductor laser bonding shown in FIG. 1; (b) is a flowchart showing the process of S104 in (a) in more detail;

FIG. 6 shows a thin film for semiconductor laser bonding of a second embodiment;

FIG. 7 shows a thin film for semiconductor laser bonding of a third embodiment;

FIG. 8 shows a thin film for semiconductor laser bonding of a fourth embodiment.

FIG. 9(a) is a surface image of sample 1 during RTA treatment; (b) is a SEM image of a cross section of sample 1 after the RTA treatment; (c) is a surface image of sample 2 during RTA treatment; (d) is a SEM image of a cross section of sample 2 after the RTA treatment; (e) is a surface image of sample 3 during RTA treatment; (f) is a SEM image of a cross section of sample 3 after the RTA treatment; (g) is a surface image of sample 4 during RTA treatment; (h) is a SEM image of a cross section of sample 4 after the RTA treatment;

FIG. 10(a) is a surface image of example 1 during RTA treatment; (b) is a SEM image of a cross section of example 1 after the RTA treatment; (c) is a surface image of example 2 during RTA treatment; (d) is a SEM image of a cross section of example 2 after the RTA treatment; (e) is a surface image of example 3 during RTA treatment; (f) is a SEM image of a cross section of example 3 after the RTA treatment; (g) is a surface image of example 4 during RTA treatment; (h) is a SEM image of a cross section of example 4 after the RTA treatment; (i) is a surface image of example 5 during RTA treatment; (j) is a SEM image of a cross section of example 5 after the RTA treatment; and

FIG. 11(a) is a surface image of example 6 during RTA treatment; (b) is a surface image of example 7 during RTA treatment; (c) is a surface image of example 8 during RTA treatment; (d) is a surface image of example 9 during RTA treatment; (e) is a surface image of comparative example 1 during RTA treatment; (f) is a surface image of comparative example 2 during RTA treatment; (g) is a surface image of comparative example 3 during RTA treatment; (h) is a surface image of comparative example 4 during RTA treatment; (i) is a surface image of comparative example 5 during RTA treatment; (j) is a surface image of comparative example 6 during RTA treatment.

### DESCRIPTION OF EMBODIMENTS

A thin film for semiconductor laser bonding of an embodiment and a method for producing the same will now be described with reference to the attached drawings. However, note that the technical scope of the present invention is not limited to embodiments thereof and covers the invention described in the claims and equivalents thereof.

### (Configuration and Function of Thin Film for Semiconductor Laser Bonding of First Embodiment)

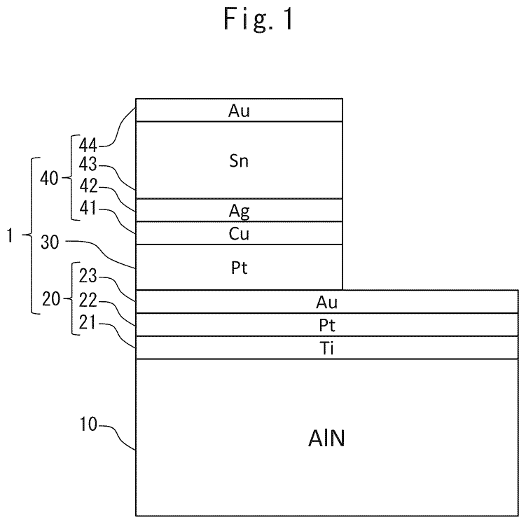

FIG. 1 shows a thin film for semiconductor laser bonding of a first embodiment.

The thin film 1 for semiconductor laser bonding is mounted on a submount substrate 10, and includes an electrode layer 20, a diffusion prevention layer 30, and a solder layer 40. A light-emitting element such as a laser diode is mounted on the solder layer 40 of the thin film 1 for semiconductor laser bonding.

The submount substrate 10 is an aluminum nitride (AlN) substrate having a rectangular planar shape and a lower thermal expansion coefficient than metal, and has a surface on which the thin film 1 for semiconductor laser bonding is disposed. The submount substrate 10 may be made of ceramics other than AlN, such as silicon carbide (SiC). The electrode layer 20 on the submount substrate 10 has a conductive pattern, and is connected to a light-emitting element mounted on the solder layer 40 via a bonding wire (not shown). Further, the submount substrate 10 is mounted on a metal stem such as a CAN package; the conductive pattern of the electrode layer and leads or the like disposed on the metal stem are connected via bonding wires.

The electrode layer 20 includes a titanium (Ti) layer 21, an electrode platinum (Pt) layer 22 laminated on the Ti layer 21, and an electrode gold (Au) layer 23 laminated on the electrode Pt layer 22. The electrode layer 20 has a conductive pattern and is connected to one electrode of a light-emitting element mounted on the solder layer 40 via a bonding wire (not shown). The Ti layer 21 is made of Ti, the electrode Pt layer 22 of Pt, and the electrode Au layer 23 of Au. The Ti layer 21 and the electrode Pt layer 22 are diffusion prevention layers that prevent the diffusion of Au contained in the electrode Au layer 23, and the electrode Au layer 23 is a pad layer to be connected to a bonding wire. The Ti layer 21 also functions as an adhesive layer for bonding to the submount substrate 10.

The diffusion prevention layer 30 is made of Pt and laminated on the electrode layer 20. The diffusion prevention layer 30 prevents tin (Sn) and Au contained in the solder layer 40 laminated on the diffusion prevention layer 30 from diffusing into the electrode layer 20. The thickness of the diffusion prevention layer 30 is preferably 0.01-0.6 μm, and more preferably 0.1-0.3 μm. If the thickness of the diffusion prevention layer 30 is greater than 0.6 μm, burrs may be made when a conductive pattern is formed by a lift-off method or the like. If the thickness of the diffusion prevention layer 30 is less than 0.01 μm, the diffusion prevention effect will be insufficient.

The solder layer 40 includes a copper (Cu) layer 41, a silver (Ag) layer 42, a Sn layer 43, and a Au layer 44, and melts when heated to a predetermined temperature, thereby mounting a light-emitting element to the submount substrate 10 via the electrode layer 20 and the diffusion prevention layer 30.

The Cu layer 41 is made of Cu and disposed all over one surface of the solder layer 40 so as to face one surface of the diffusion prevention layer 30. The Cu layer 41 is a layer for producing an appropriate intermetallic compound between the diffusion prevention layer 30 and the solder layer 40 at heating of the solder layer 40. The Cu layer 41 disposed all over one surface of the solder layer 40 reduces the rate at which Cu is mixed into the Sn layer 43, enabling elevation of the melting point of the solder layer 40 to be gradual.

The Cu content in the solder layer 40 is preferably 0.1-10.1 wt %. If the Cu content is less than 0.1 wt %, a reaction between the diffusion prevention layer 23 and the Sn layer 43 will occur early at heating of the solder layer 40, and the melting duration, which is the time during which the solder layer 40 remains in a molten state, will be significantly reduced. When the Cu content in the solder layer 40 is 0.1-10.1 wt %, not many voids occur and high reliability can be achieved. If the Cu content is greater than 10.1 wt %, many voids may occur at the interface between the diffusion prevention layer 30 and the solder layer 40 at heating of the solder layer 40.

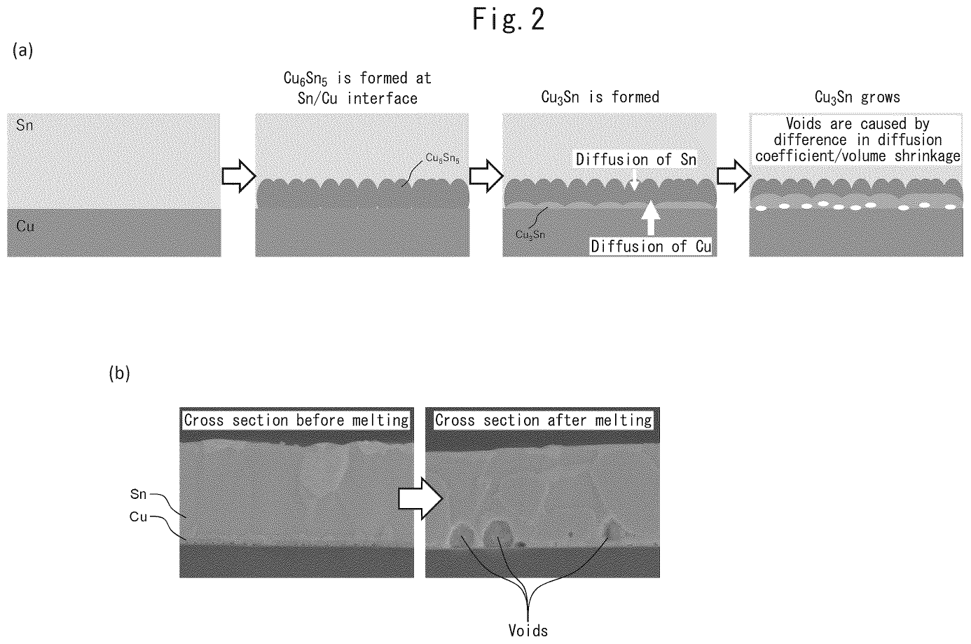

FIG. 2(a) shows the state of a reaction that occurs between Cu contained in the Cu layer 41 and Sn contained in the Sn layer 43 when the thin film 1 for semiconductor laser bonding is heated. FIG. 2(b) shows photographs of a cross section of the thin film 1 for semiconductor laser bonding before and after melting. Although in the solder layer 40 the Ag layer 42 is disposed between the Cu layer 41 and the Sn layer 43, the Ag content in the Ag layer 42 of the solder layer 40 is low. Even if the Ag layer 42 is present, a reaction occurs between Cu contained in the Cu layer 41 and Sn contained in the Sn layer 43, and the effect of this reaction is significant. Thus the reaction state will be described herein without the Ag layer 42.

As the thin film 1 for semiconductor laser bonding is heated, Cu and Sn react to produce Cu6Sn5, strengthening the bond between the Cu layer 41 and the Sn layer 43, and consequently enhancing the adhesion between the diffusion prevention layer 30 and the solder layer 40. After Cu6Sn5 is formed, a further reaction between Cu and Sn produces Cu3Sn instead of Cu6Sn5. While Cu6Sn5 is being produced, the amounts of diffusion of Cu and Sn are approximately the same. However, when Cu3Sn is produced instead, the amount of diffusion of Cu becomes greater than that of Sn, which increases the risk of voids occurring inside the Cu layer 41 and Cu3Sn. The thickness of the Cu layer 41 and the Cu content in the solder layer 40 are adjusted so that Cu6Sn5 is produced and that Cu3Sn is not produced.

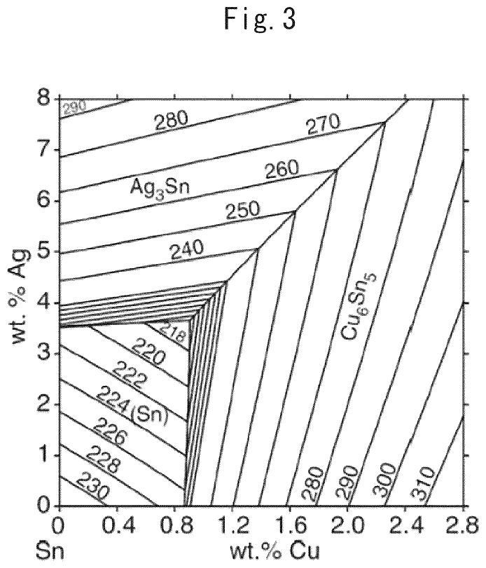

The Ag layer 42 is made of Ag and disposed so as to cover the whole upper surface of the Cu layer 41. Ag contained in the solder layer 40 mitigates the degradation of the solder layer 40 caused by a heat cycle test or the like, and improves the reliability of the solder layer. The Ag content in the solder layer 40 is preferably 0.1-4.4 wt %. If the Ag content is less than 0.1 wt %, the effect of reliability improvement provided by containing Ag will not be substantially achieved. When the Ag content is 0.1-4.4 wt %, the melting point can be lowered. FIG. 3 is a Sn—Ag—Cu phase diagram. The lowering of the melting point caused by containing a small amount of Ag can be qualitatively explained by the Sn—Ag—Cu phase diagram. In FIG. 3, the horizontal axis represents the Cu content in Sn—Ag—Cu alloy, the vertical axis represents the Ag content in Sn—Ag—Cu alloy, and the numbers in the diagram indicate melting points. It can be seen that the melting point increases as the Ag content increases above 4.5 wt %. In the solder layer 40, which contains Au of the Au layer 44 in addition to Sn, Ag, and Cu and is also affected by contamination of Pt from the diffusion prevention layer 30, if the Ag content is greater than 4.5 wt %, the melting point of the solder layer 40 will be higher than 210° C., making it difficult to have a low melting point.

The Sn layer 43 is made of Sn and disposed so as to cover the whole upper surface of the Ag layer 42. Sn is a main component of the solder layer 40, and the Sn content in the solder layer 40 is preferably 83.1-92.0 wt %, and more preferably 83.1-88.7 wt %. The solder layer 40 is a low-melting solder containing Sn as a main component. AuSn (8:2 wt %) thin-film solder commonly used for mounting laser diodes has high reliability. However, AuSn (8:2 wt %) thin-film solder has a high melting point of 278° C., and thermal stress occurring at mounting a laser diode may cause the degradation of light-emitting characteristics of the laser diode, such as a blue shift in the emission wavelength and a decrease in light output caused by transition of the active layer. Sn contained in the solder layer 40 as a main component enables a lower melting point, increased ductility, and reduced stress.

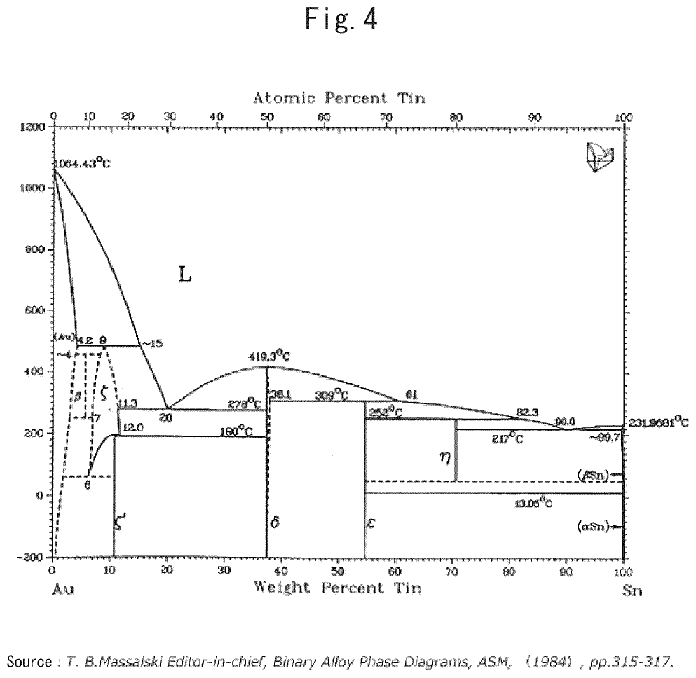

The Au layer 44 is made of Au and disposed so as to cover the whole upper surface of the Sn layer 43. A small amount of Au contained in the solder layer 40 enables the solder layer 40 to have a low melting point. FIG. 4 is a Au—Sn phase diagram. The lowering of the melting point caused by containing a small amount of Au can be qualitatively explained by the Au—Sn phase diagram. The Au—Sn phase diagram suggests that the melting point of a Au—Sn alloy is approximately 240° C. or less when the Au content is less than 14.0 wt %. Thus the Au content in the solder layer 40 is preferably 0.1-14.0 wt %. If the Au content is less than 0.1 wt %, the effect of lowering the melting point provided by containing Au will not be substantially achieved. In the solder layer 40, which contains Sn, Ag, and Cu in addition to Au and is also affected by contamination of Pt from the diffusion prevention layer 30, when the Au content is 0.1-14.0 wt %, the melting point of the thin film 1 for semiconductor laser bonding is 210° C. or less, making it possible to have a low melting point. If the Au content is greater than 14.0 wt %, the melting point of the thin film 1 for semiconductor laser bonding will be higher than 210° C., making it difficult to have a low melting point.

In the thin film 1 for semiconductor laser bonding, the remainder except the above components is impurities. Impurities are components that are mixed in, when the thin film 1 for semiconductor laser bonding is produced industrially, because of various factors in the production process, and are contained to an extent that does not affect the characteristics of the thin film 1 for semiconductor laser bonding.

The solder layer 40 has favorable characteristics and is usable when containing 7.2-14.0 wt % Au, 0.1-4.4 wt % Ag, and 0.1-10.1 wt % Cu with the remainder except unavoidable impurities being Sn. Such composition enables the solder layer 40 to have favorable characteristics of having a melting point of 210° C. or less, not having many voids, and having a melting duration of 5 seconds or more. Since optical elements such as semiconductor lasers are mounted within a few seconds after solder melts, it is desirable for the melting duration to be 5 seconds or more.

It is more preferable that the solder layer 40 have a Cu content of 0.1 wt % or more but less than 10.1 wt % and a Ag content of 0.1 wt % or more but 3.1 wt % or less. When the solder layer 40 has a Cu content of 0.1 wt % or more but less than 10.1 wt % and a Ag content of 0.1 wt % or more but 3.1 wt % or less, there is no risk of voids occurring, the melting point can be lowered, and higher reliability can be achieved. The lowering of the melting point caused by containing a small amount of Cu can be qualitatively explained by the Sn—Ag—Cu phase diagram shown in FIG. 3. It can be seen that the melting point of a Sn—Ag—Cu alloy containing a small amount of Cu is lower as the Cu content is lower.

It is more preferable that the solder layer 40 have a Ag content of 0.1-3.1 wt % and a Cu content of 0.1-6.7 wt %. When the Ag content is 0.1-3.1 wt % and the Cu content is 0.1-6.7 wt %, the melting point can be lowered, voids do not occur, and high reliability can be achieved.

The Au content in the solder layer 40 is more preferably 7.3-14.0 wt %. When the Au content is 7.3-14.0 wt %, the melting point of the thin film 1 for semiconductor laser bonding is 205° C., making it possible to have a lower melting point.

The Au content in the solder layer 40 is more preferably 7.3-8.0 wt %, and even more preferably 7.3-7.7 wt %. When the Au content is 7.3-7.7 wt %, the melting duration is 15 seconds or more.

It is more preferable that the solder layer 40 have a Ag content of 0.1-4.4 wt % and a Cu content of 0.1-6.7 wt %. When the Ag content is 0.1-4.4 wt % and the Cu content is 0.1-6.7 wt %, the melting point of the solder layer 40 is 205° C., making it possible to have a low melting point.

It is more preferable that the solder layer 40 contain 7.3-7.7 wt % Au, 0.1-3.1 wt % Ag, and 0.5-6.7 wt % Cu with the remainder except unavoidable impurities being Sn. Such composition enables the solder layer 40 to have more favorable characteristics of having a melting point of 205° C., not having voids, and having a melting duration of 15 seconds or more.

Since Ag contained in the Ag layer 42 and Au contained in the Au layer 44 diffuse into the Sn layer 43 even at room temperature, the Ag layer 42, the Sn layer 43, and the Au layer 44 may be an integrated layer.

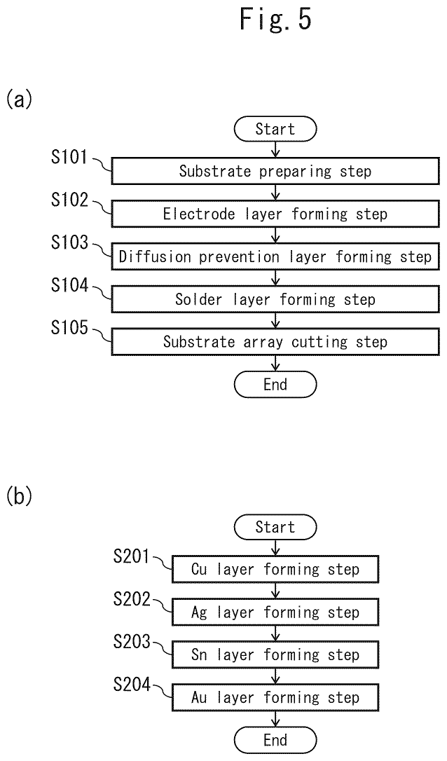

FIG. 5(a) is a flowchart showing a method for producing a thin film 1 for semiconductor laser bonding.

First, in a substrate preparing step, a substrate array is disposed inside a vacuum chamber of production equipment (S101). The substrate array is a flat plate-shaped member made of AlN and serving as a submount substrate 10. After the substrate array is disposed inside the vacuum chamber, the inside of the vacuum chamber is evacuated to a vacuum.

Next, in an electrode layer forming step, an electrode layer 20 is formed (S102). An electrode layer 20 is formed by depositing a Ti layer 21, an electrode Pt layer 22, and an electrode Au layer 23 sequentially by a vacuum deposition process such as sputtering.

Next, in a diffusion prevention layer forming step, a diffusion prevention layer 30 is formed (S103). A diffusion prevention layer 30 is formed by depositing Pt on the electrode layer 20 by a vacuum deposition process, as in the electrode layer forming step. The area where no diffusion prevention layer 30 is to be deposited is covered with a resist film.

Next, in a solder layer forming step, a solder layer 40 is formed on the diffusion prevention layer 30 (S104).

FIG. 5(b) is a flowchart showing the process of S104 in more detail.

First, in a Cu layer forming step, a Cu layer 41 is formed (S201). A Cu layer 41 is formed by depositing Cu on the diffusion prevention layer 30 by a vacuum deposition process. The thickness of the deposited Cu layer 41 is determined depending on the Cu content in the solder layer 40.

Next, in a Ag layer forming step, a Ag layer 42 is formed (S202). A Ag layer 42 is formed by depositing Ag on the Cu layer 41 by a vacuum deposition process. The thickness of the deposited Ag layer 42 is determined depending on the Ag content in the solder layer 40.

Next, in a Sn layer forming step, a Sn layer 43 is formed (S203). A Sn layer 43 is formed by depositing Sn on the Ag layer 42 by a vacuum deposition process. The thickness of the deposited Sn layer 43 is determined depending on the Sn content in the solder layer 40.

Then, in a Au layer forming step, a Au layer 44 is formed (S204). A Au layer 44 is formed by depositing Au on the Sn layer 43 by a vacuum deposition process. The thickness of the deposited Au layer 44 is determined depending on the Au content in the solder layer 40.

Then, in a substrate array cutting step, the substrate array is cut (S105) to form multiple thin films 1 for semiconductor laser bonding, and the production process of the thin film 1 for semiconductor laser bonding is completed. In the substrate array cutting step, the resist film covering the electrode layer 20 is removed before the substrate array is cut.

### (Configuration and Function of Thin Film for Semiconductor Laser Bonding of Second Embodiment)

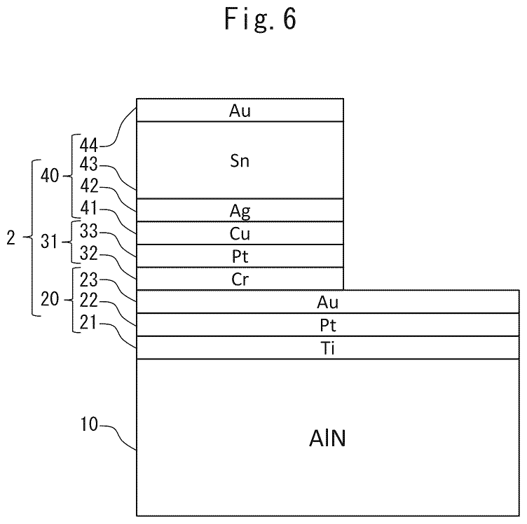

FIG. 6 shows a thin film for semiconductor laser bonding of a second embodiment.

The thin film 2 for semiconductor laser bonding differs from the thin film 1 for semiconductor laser bonding in that a diffusion prevention layer 31 is included instead of the diffusion prevention layer 30. The configurations and functions of components of the thin film 2 for semiconductor laser bonding except the diffusion prevention layer 31 are the same as those of the thin film 1 for semiconductor laser bonding assigned the same reference numerals, so a detailed description thereof is omitted herein.

The diffusion prevention layer 31 includes a chromium (Cr) layer 32 and a Pt layer 33. The Cr layer 32 is an adhesive layer that enhances the adhesion between the electrode layer 20 and the diffusion prevention layer 31. Disposing the Cr layer 32 prevents the electrode layer 20 and the solder layer 40 from mixing with each other even if the Pt layer 33 is completely consumed by a reaction with the solder layer 40, providing a sufficient diffusion prevention effect. The thickness of the Cr layer 32 is preferably 0.01-0.2 μm, and more preferably 0.03-0.1 μm. If the thickness of the Cr layer 32 is greater than 0.2 μm, peeling from the electrode layer 20 may be induced by the strong stress of Cr itself. If the thickness of the Cr layer 32 is less than 0.01 μm, a sufficient diffusion prevention effect will not be substantially achieved.

The Pt layer 33 prevents Sn and Au contained in the solder layer 40 from diffusing into the electrode layer 20. The thickness of the Pt layer 33 is preferably 0.01-0.6 μm, and more preferably 0.1-0.3 μm.

The production method of the thin film 2 for semiconductor laser bonding is the same as that of the thin film 1 for semiconductor laser bonding except that a step of laminating the diffusion prevention layer 31 on the electrode layer 20 is included, so a detailed description thereof is omitted herein.

### (Configuration and Function of Thin Film for Semiconductor Laser Bonding of Third Embodiment)

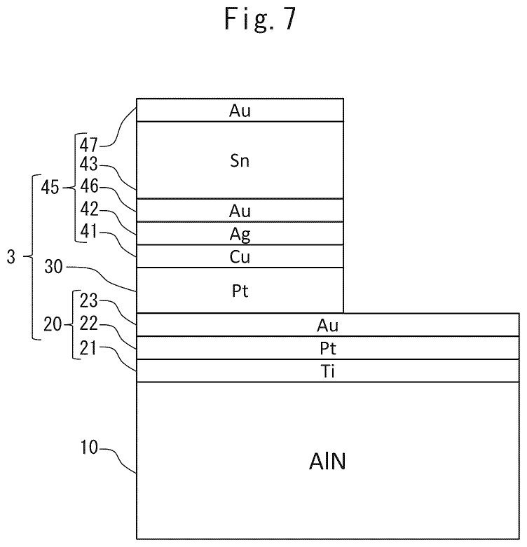

FIG. 7 shows a thin film for semiconductor laser bonding of a third embodiment.

The thin film 3 for semiconductor laser bonding differs from the thin film 1 for semiconductor laser bonding in that a solder layer 45 is included instead of the solder layer 40. The configurations and functions of components of the thin film 3 for semiconductor laser bonding except the solder layer 45 are the same as those of the thin film 1 for semiconductor laser bonding assigned the same reference numerals, so a detailed description thereof is omitted herein.

The solder layer 45 differs from the solder layer 40 in that a first Au layer 46 and a second Au layer 47 are included instead of the Au layer 44. The configurations and functions of components of the solder layer 45 except the first Au layer 46 and the second Au layer 47 are the same as those of the solder layer 40 assigned the same reference numerals, so a detailed description thereof is omitted herein.

The first Au layer 46 and the second Au layer 47 are made of Au. The first Au layer 46 is disposed between the Ag layer 42 and the Sn layer 43, and the second Au layer 47 is disposed on the upper surface of the Sn layer 43, similarly to the Au layer 44. The first Au layer 46 and the second Au layer 47 are disposed so as to contain such an amount of Au in total that the Au content in the solder layer 45 is 0.1-14.0 wt %. The first Au layer 46 is disposed between the Ag layer 42 and the Sn layer 43, but may be disposed between the Cu layer 41 and the Ag layer 42.

The production method of the thin film 3 for semiconductor laser bonding is the same as that of the thin film 1 for semiconductor laser bonding except that a step of laminating the first Au layer 46 between the Ag layer 42 and the Sn layer 43 is included, so a detailed description thereof is omitted herein.

### (Configuration and Function of Thin Film for Semiconductor Laser Bonding of Fourth Embodiment)

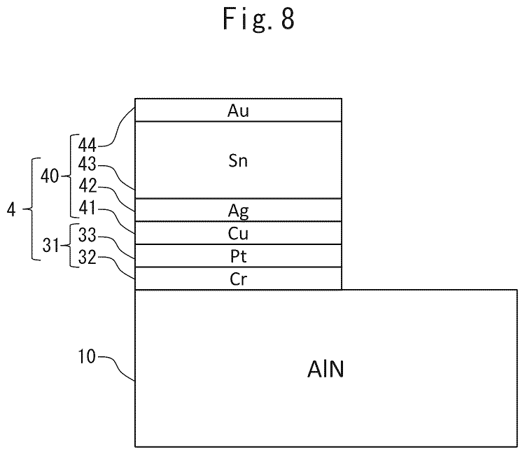

FIG. 8 shows a thin film for semiconductor laser bonding of a fourth embodiment.

The thin film 4 for semiconductor laser bonding differs from the thin film 2 for semiconductor laser bonding in that the electrode layer 20 is not included. The thin film 4 for semiconductor laser bonding adheres to the submount substrate 10 by the Cr layer 32 of the diffusion prevention layer 31, which is an adhesive layer, adhering to the submount substrate 10.

The production method of the thin film 4 for semiconductor laser bonding is the same as that of the thin film 1 for semiconductor laser bonding except that the electrode layer forming step is not included, so a detailed description thereof is omitted herein.

### (Layer Configuration of Diffusion Prevention Layer and Solder Layer)

Table 1 shows the layer configuration of the diffusion prevention layer and layers in the solder layer that are disposed below the Sn layer and the Au layer disposed on the Sn layer. In each of samples 1-4 shown in Table 1, a 3.0-μm-thick Sn layer is laminated on lower layers laminated on an AlN substrate, and a 0.16-μm-thick Au layer is sequentially laminated on the Sn layer.

TABLE 1

| | Layer configuration of lower layers | | | | | | |
|---|---|---|---|---|---|---|---|
| | First | Second | Third | Fourth | | | |
| | layer | layer | layer | layer | Meltability | Voids | Evaluation |
| Sample 1 | Cr (0.05) | Ni (0.20) | — | — | X | X | X |
| Sample 2 | Ti (0.05) | Pt (0.20) | — | — | X | ◯ | X |
| Sample 3 | Cr (0.05) | Cu (0.20) | Ag (0.074) | — | ◯ | X | X |
| Sample 4 | Cr (0.05) | Pt (0.10) | Cu (0.10) | Ag (0.074) | ◯ | Δ | ◯ |

A 3.0-μm-thick Sn layer and a 0.16-μm-thick Au layer are sequentially laminated on the lower layers

In Table 1, the “Layer configuration of lower layers” columns show the layer configuration of the layers below the Sn layer and the Au layer; “First layer” is the bottom layer; “Second layer” is a layer laminated on the “First layer”; “Third layer” is a layer laminated on the “Second layer”; “Fourth layer” is a layer laminated on the “Third layer.”

The “Meltability” column shows meltability at rapid thermal annealing (RTA) treatment at 220° C. In the RTA treatment, a pulse heater manufactured by Ichinen Manufacturing Co., Ltd was used to increase the temperature to 220° C. within a few seconds, and the temperature was maintained for 20 seconds. In the “Meltability” column, “O” indicates that the sample remained in a molten state for 15 seconds or more when heated at 220° C., and “X” indicates that the sample remained in a molten state for less than 1 second when heated at 220° C. The “Voids” column shows the state of occurrence of voids after the RTA treatment at 220° C. In the “Voids” column, “O” indicates that no voids occurred, “Δ” indicates that a few voids occurred, and “X” indicates that many voids occurred. The “Evaluation” column is an overall rating of meltability and voids. In the “Evaluation” column, “O” indicates good, and “X” indicates bad.

Sample 1 includes a 0.05-μm-thick Cr layer as a first layer, a 0.20-μm-thick nickel (Ni) layer as a second layer, a 3.0-μm-thick Sn layer on the Ni layer, and a 0.16-μm-thick Au layer on the Sn layer; these layers are sequentially laminated.

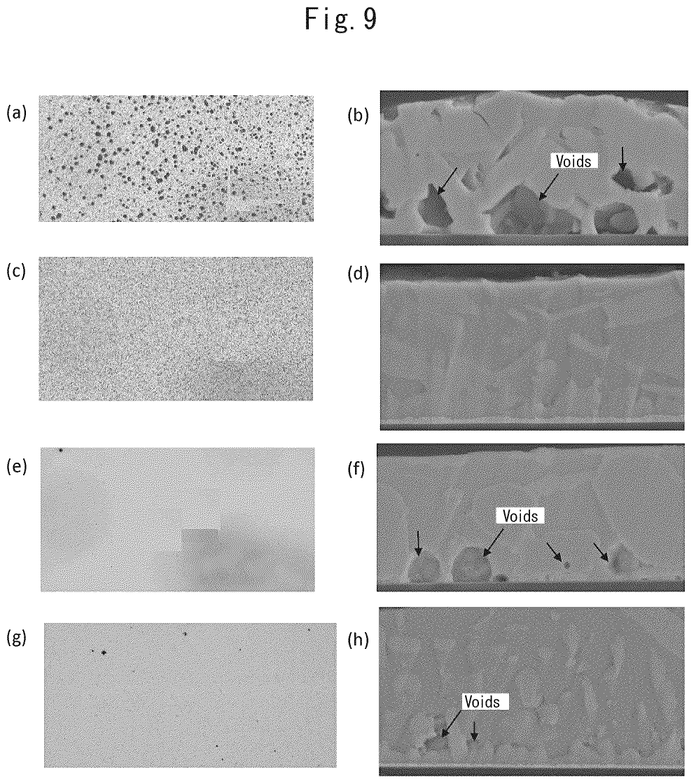

FIG. 9(a) is a surface image of sample 1 during RTA treatment; FIG. 9(b) is a scanning electron microscope (SEM) image of a cross section of sample 1 after the RTA treatment.

Sample 1 remained in a molten state for less than 1 second in RTA treatment, and had many voids after the RTA treatment. Thus, both the “Meltability” and “Voids” columns were “X,” and the “Evaluation” column was “X.”

Sample 2 includes a 0.05-μm-thick Ti layer as a first layer, a 0.20-μm-thick Pt layer as a second layer, a 3.0-μm-thick Sn layer on the Pt layer, and a 0.16-μm-thick Au layer on the Sn layer; these layers are sequentially laminated.

FIG. 9(c) is a surface image of sample 2 during RTA treatment; FIG. 9(d) is a SEM image of a cross section of sample 2 after the RTA treatment.

Sample 2 had no voids after RTA treatment, so the “Voids” column was “O.” However, the sample remained in a molten state for less than 1 second in the RTA treatment, so the “Meltability” column was “X” and the “Evaluation” column was “X.”

Sample 3 includes a 0.05-μm-thick Cr layer as a first layer, a 0.20-μm-thick Cu layer as a second layer, and a 0.074-μm-thick Sn layer as a third layer; the sample includes a 3.0-μm-thick Sn layer on the Ag layer and a 0.16-μm-thick Au layer on the Sn layer; these layers are sequentially laminated.

FIG. 9(e) is a surface image of sample 3 during RTA treatment; FIG. 9(f) is a SEM image of a cross section of sample 3 after the RTA treatment.

Sample 3 remained in a molten state for 15 seconds or more in RTA treatment, so the “Meltability” column was “O.” However, the sample had many voids after the RTA treatment, so the “Voids” column was “X” and the “Evaluation” column was “X.”

The sample 4 has a layer structure corresponding to the thin film 2 for semiconductor laser bonding. Sample 4 includes a 0.05-μm-thick Cr layer as a first layer, a 0.1-μm-thick Pt layer as a second layer, a 0.1-μm-thick Cu layer as a third layer, and a 0.74-μm-thick Ag layer as a fourth layer; the sample includes a 3.0-μm-thick Sn layer on the Ag layer and a 0.16-μm-thick Au layer on the Sn layer; these layers are sequentially laminated.

FIG. 9(g) is a surface image of sample 4 during RTA treatment; FIG. 9(f) is a SEM image of a cross section of sample 4 after the RTA treatment.

Sample 4 had a few voids after RTA treatment, so the “Voids” column was “Δ.” However, the sample remained in a molten state for 15 seconds or more in the RTA treatment, so the “Meltability” column was “O” and the “Evaluation” column was “O.” The difference between sample 4 and sample 3 is whether a Pt layer is disposed between the Cr layer and the Cu layer. In sample 4, voids are reduced by a Pt layer being disposed. Sample 4 has the same layer structure as the thin film 4 for semiconductor laser bonding. However, the thin films 1-3 for semiconductor laser bonding also have the effect of the layer structure in sample 4 like the thin film 4 for semiconductor laser bonding.

### Example 1

### (Au, Sn, Ag, and Cu Contents in Solder Layer)

Table 2 shows the Au, Sn, Ag, and Cu contents in the solder layer. Each of examples 1-9 and comparative examples 1-6 shown in Table 2 is formed by sequentially laminating a Cu layer, a Ag layer, a Sn layer, and a Au layer on a diffusion prevention layer composed of a Cr layer and a Pt layer laminated on a submount substrate made of AlN. Each of examples 1-9 and comparative examples 1-6 has the same layer structure as the thin film 4 for semiconductor laser bonding. However, the thin films 1-3 for semiconductor laser bonding also have the effect of the Au, Sn, Ag, and Cu contents in the solder layers of examples 1-9 and comparative examples 1-6 like the thin film 4 for semiconductor laser bonding.

TABLE 2

| | Content | | | | Melting | | Melting | |
|---|---|---|---|---|---|---|---|---|
| | Au | Sn | Ag | Cu | point | Voids | duration | Score |
| Example 1 | 8.0% | 91.8% | 0.1% | 0.1% | ◯ | ◯ | Δ | 5 |
| Example 2 | 7.7% | 88.6% | 3.1% | 0.5% | ◯ | ◯ | ◯ | 6 |
| Example 3 | 7.6% | 87.5% | 3.1% | 1.8% | ◯ | ◯ | ◯ | 6 |
| Example 4 | 7.5% | 86.0% | 3.0% | 3.5% | ◯ | ◯ | ◯ | 6 |
| Example 5 | 7.3% | 83.1% | 2.9% | 6.7% | ◯ | ◯ | ◯ | 6 |
| Example 6 | 14.0% | 80.0% | 2.8% | 3.2% | ◯ | ◯ | Δ | 5 |
| Example 7 | 7.7% | 88.6% | 0.1% | 3.6% | ◯ | ◯ | ◯ | 6 |
| Example 8 | 7.4% | 84.7% | 4.4% | 3.4% | ◯ | Δ | ◯ | 5 |
| Example 9 | 7.2% | 82.7% | 0.1% | 10.1% | Δ | ◯ | ◯ | 5 |
| Comparative | 7.0% | 80.4% | 2.8% | 9.8% | ◯ | X | Δ | 3 |
| example 1 | | | | | | | | |
| Comparative | 6.8% | 77.8% | 2.7% | 12.6% | ◯ | X | Δ | 3 |
| example 2 | | | | | | | | |
| Comparative | 6.6% | 75.5% | 2.7% | 15.3% | ◯ | X | Δ | 3 |
| example 3 | | | | | | | | |
| Comparative | 19.6% | 74.8% | 2.6% | 3.0% | Δ | ◯ | X | 3 |
| example 4 | | | | | | | | |
| Comparative | 24.5% | 70.2% | 2.5% | 2.8% | X | ◯ | X | 2 |
| example 5 | | | | | | | | |
| Comparative | 6.9% | 79.0% | 4.5% | 9.6% | Δ | Δ | ◯ | 4 |
| example 6 | | | | | | | | |

Melting point: “◯” 205° C., “Δ” 210° C., “X” >> 210° C.
Voids: “◯” none, “Δ” a few, “X” many
Melting duration: “◯” 15 seconds or more, “Δ” 5 seconds or more but less than 15 seconds, “X” less than 5 seconds

In Table 2, the “Content” columns show the Au, Sn, Ag, and Cu contents in the solder layer. The “Au” column shows the Au content in the solder layer in wt %; the “Sn” column shows the Sn content in the solder layer in wt %; the “Ag” column shows the Ag content in the solder layer in wt %; the “Cu” column shows the Cu content in the solder layer in wt %.

The “Melting point” column shows whether the melting point at RTA treatment was good or bad. In the RTA treatment, a pulse heater manufactured by Ichinen Manufacturing Co., Ltd was used to increase the temperature gradually from room temperature to 240° C. In the “Melting point” column, “O” indicates that the melting point was 205° C., “Δ” indicates that the melting point was 210° C., and “X” indicates that the melting point was higher than 210° C. The “Voids” column shows the state of occurrence of voids after the RTA treatment at 220° C. In the “Voids” column, “O” indicates that no voids occurred, “Δ” indicates that a few voids occurred, and “X” indicates that many voids occurred. The “Melting duration” column shows the time during which the molten state continued in the RTA treatment at 220° C. In the “Melting duration” column, “O” indicates that the molten state continued for 15 seconds or more, “Δ” indicates that the molten state continued for 5 seconds or more but less than 15 seconds, and “X” indicates that the molten state continued for less than 5 seconds.

The “Score” column shows values obtained by scoring an overall rating of meltability, voids, and melting duration. The values shown in the “Score” column are scored as 2 points for “O” in the “Melting Point,” “Voids,” and “Melting duration” columns, 1 point for “Δ,” and 0 points for “X.” When the score is 6 points, the composition of the solder layer is considered to be within an optimal composition range. When the score is 5 points, the composition of the solder layer is considered to be within a composition range that is not optimal but is usable. When the score is 4 points or less, the composition of the solder layer is considered to be in an unusable composition range.

Example 1 was formed by sequentially laminating Cu, Ag, Sn, and Au. Example 1 contains 8.0 wt % Au, 91.8 wt % Sn, 0.1 wt % Ag, and 0.1 wt % Cu.

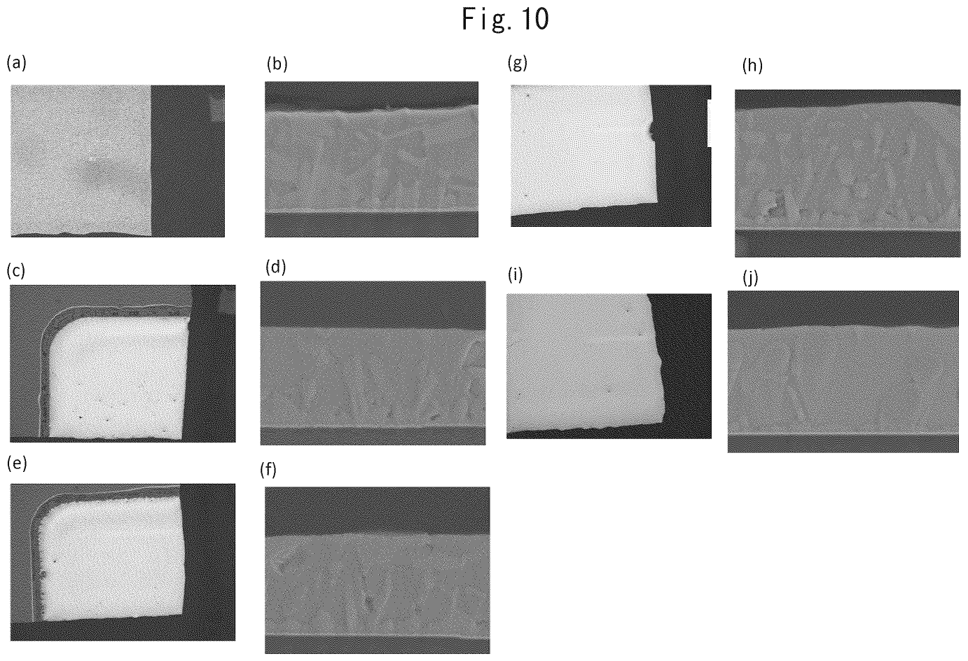

FIG. 10(a) is a surface image of example 1 during RTA treatment; FIG. 10(b) is a SEM image of a cross section of example 1 after the RTA treatment.

In example 1, the melting point was 205° C., so the “Melting point” column was “O”; no voids occurred after the RTA treatment, so the “Voids” column was “O”; the molten state continued for about 5 seconds, so the “Melting duration” column was “Δ.” Since the “Melting point” column was “O,” the “Voids” column was “O,” and the “Melting duration” column was “Δ,” the score of example 1 was 5 points.

Example 2 was formed by sequentially laminating Cu, Ag, Sn, and Au. Example 2 contains 7.7 wt % Au, 88.6 wt % Sn, 3.1 wt % Ag, and 0.5 wt % Cu.

FIG. 10(c) is a surface image of example 2 during RTA treatment; FIG. 10(d) is a SEM image of a cross section of example 2 after the RTA treatment.

In example 2, the melting point was 205° C., so the “Melting point” column was “O”; no voids occurred after the RTA treatment, so the “Voids” column was “O”; the molten state continued for about 15 seconds or more, so the “Melting duration” column was “O.” Since the “Melting point” column was “O,” the “Voids” column was “O,” and the “Melting duration” column was “O,” the score of example 2 was 6 points.

Example 3 was formed by sequentially laminating Cu, Ag, Sn, and Au. Example 3 contains 7.6 wt % Au, 87.5 wt % Sn, 3.1 wt % Ag, and 1.8 wt % Cu.

FIG. 10(e) is a surface image of example 3 during RTA treatment; FIG. 10(f) is a SEM image of a cross section of example 3 after the RTA treatment.

In example 3, the melting point was 205° C., so the “Melting point” column was “O”; no voids occurred after the RTA treatment, so the “Voids” column was “O”; the molten state continued for about 15 seconds or more, so the “Melting duration” column was “O.” Since the “Melting point” column was “O,” the “Voids” column was “O,” and the “Melting duration” column was “O,” the score of example 3 was 6 points.

Example 4 was formed by sequentially laminating Cu, Ag, Sn, and Au. Example 4 contains 7.5 wt % Au, 86.0 wt % Sn, 0.3 wt % Ag, and 3.5 wt % Cu.

FIG. 10(g) is a surface image of example 4 during RTA treatment; FIG. 10(h) is a SEM image of a cross section of example 4 after the RTA treatment.

In example 4, the melting point was 205° C., so the “Melting point” column was “O”; no voids occurred after the RTA treatment, so the “Voids” column was “O”; the molten state continued for about 15 seconds or more, so the “Melting duration” column was “O.” Since the “Melting point” column was “O,” the “Voids” column was “O,” and the “Melting duration” column was “O,” the score of example 4 was 6 points.

Example 5 was formed by sequentially laminating Cu, Ag, Sn, and Au. Example 5 contains 7.3 wt % Au, 83.1 wt % Sn, 2.9 wt % Ag, and 6.7 wt % Cu.

FIG. 10(i) is a surface image of example 5 during RTA treatment; FIG. 10(j) is a SEM image of a cross section of example 5 after the RTA treatment.

In example 5, the melting point was 205° C., so the “Melting point” column was “O”; no voids occurred after the RTA treatment, so the “Voids” column was “O”; the molten state continued for about 15 seconds or more, so the “Melting duration” column was “O.” Since the “Melting point” column was “O,” the “Voids” column was “O,” and the “Melting duration” column was “O,” the score of example 5 was 6 points.

Example 6 was formed by sequentially laminating Cu, Ag, Sn, and Au. Example 6 contains 14.0 wt % Au, 80.0 wt % Sn, 2.8 wt % Ag, and 3.2 wt % Cu.

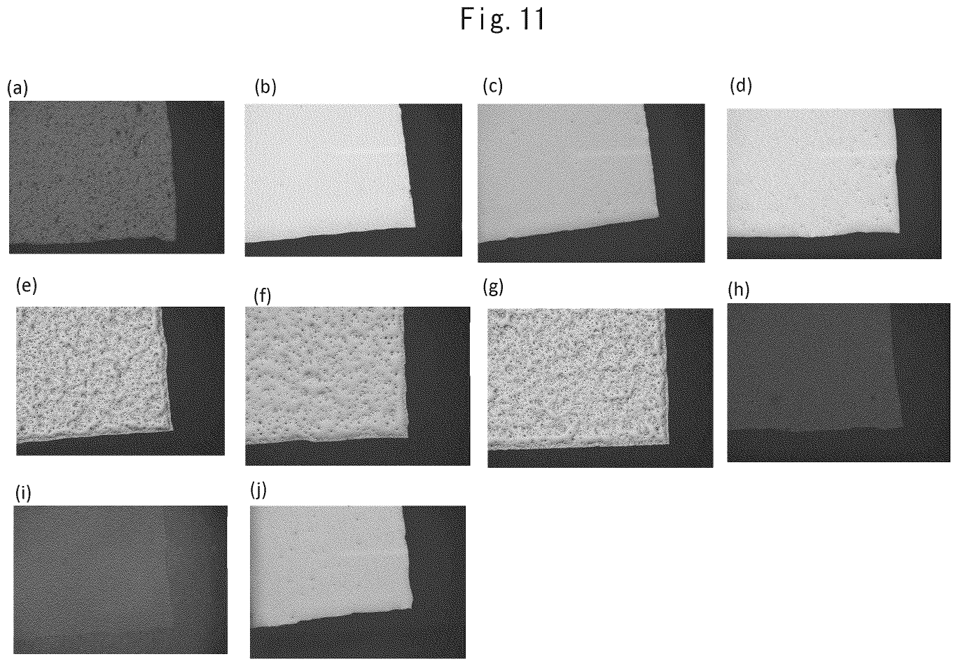

FIG. 11(a) is a surface image of example 6 during RTA treatment.

In example 6, the melting point was 205° C., so the “Melting point” column was “O”; no voids occurred after the RTA treatment, so the “Voids” column was “O”; the molten state continued for about 5 seconds, so the “Melting duration” column was “Δ.” Since the “Melting point” column was “O,” the “Voids” column was “O,” and the “Melting duration” column was “Δ,” the score of example 6 was 5 points.

Example 7 was formed by sequentially laminating Cu, Ag, Sn, and Au. Example 7 contains 7.7 wt % Au, 88.6 wt % Sn, 0.1 wt % Ag, and 3.6 wt % Cu.

FIG. 11(b) is a surface image of example 7 during RTA treatment.

In example 7, the melting point was 205° C., so the “Melting point” column was “O”; no voids occurred after the RTA treatment, so the “Voids” column was “O”; the molten state continued for about 5 seconds, so the “Melting duration” column was “Δ.” Since the “Melting point” column was “O,” the “Voids” column was “O,” and the “Melting duration” column was “Δ,” the score of example 7 was 5 points.

Example 8 was formed by sequentially laminating Cu, Ag, Sn, and Au. Example 8 contains 7.4 wt % Au, 84.7 wt % Sn, 4.4 wt % Ag, and 3.4 wt % Cu.

FIG. 11(c) is a surface image of example 8 during RTA treatment.

In example 8, the melting point was 205° C., so the “Melting point” column was “O”; no voids occurred after the RTA treatment, so the “Voids” column was “O”; the molten state continued for about 5 seconds, so the “Melting duration” column was “Δ.” Since the “Melting point” column was “O,” the “Voids” column was “O,” and the “Melting duration” column was “Δ,” the score of example 8 was 5 points.

Example 9 was formed by sequentially laminating Cu, Ag, Sn, and Au. Example 9 contains 7.2 wt % Au, 82.7 wt % Sn, 0.1 wt % Ag, and 10.1 wt % Cu.

FIG. 11(d) is a surface image of example 9 during RTA treatment.

In example 9, the melting point was 210° C., so the “Melting point” column was “Δ”; no voids occurred after the RTA treatment, so the “Voids” column was “O”; the molten state continued for about 15 seconds or more, so the “Melting duration” column was “O.” Since the “Melting point” column was “O,” the “Voids” column was “O,” and the “Melting duration” column was “Δ,” the score of example 9 was 5 points.

Comparative example 1 was formed by sequentially laminating Cu, Ag, Sn, and Au. Comparative example 1 contains 7.0 wt % Au, 80.4 wt % Sn, 2.8 wt % Ag, and 9.8 wt % Cu.

FIG. 11(e) is a surface image of comparative example 1 during RTA treatment.

In comparative example 1, the melting point was 205° C., so the “Melting point” column was “O”; many voids occurred after the RTA treatment, so the “Voids” column was “X”; the molten state continued for about 5 seconds, so the “Melting duration” column was “Δ.” Since the “Melting point” column was “O,” the “Voids” column was “X,” and the “Melting duration” column was “Δ,” the score of comparative example 1 was 3 points.

Comparative example 2 was formed by sequentially laminating Cu, Ag, Sn, and Au. Comparative example 2 contains 6.8 wt % Au, 77.8 wt % Sn, 2.7 wt % Ag, and 12.6 wt % Cu.

FIG. 11(f) is a surface image of comparative example 2 during RTA treatment.

In comparative example 2, the melting point was 205° C., so the “Melting point” column was “O”; many voids occurred after the RTA treatment, so the “Voids” column was “X”; the molten state continued for about 5 seconds, so the “Melting duration” column was “Δ.” Since the “Melting point” column was “O,” the “Voids” column was “X,” and the “Melting duration” column was “Δ,” the score of comparative example 2 was 3 points.

Comparative example 3 was formed by sequentially laminating Cu, Ag, Sn, and Au. Comparative example 3 contains 6.6 wt % Au, 77.5 wt % Sn, 2.7 wt % Ag, and 15.3 wt % Cu.

FIG. 11(g) is a surface image of comparative example 3 during RTA treatment.

In comparative example 3, the melting point was 205° C., so the “Melting point” column was “O”; many voids occurred after the RTA treatment, so the “Voids” column was “X”; the molten state continued for about 5 seconds, so the “Melting duration” column was “Δ.” Since the “Melting point” column was “O,” the “Voids” column was “X,” and the “Melting duration” column was “Δ,” the score of comparative example 3 was 3 points.

Comparative example 4 was formed by sequentially laminating Cu, Ag, Sn, and Au. Comparative example 4 contains 19.6 wt % Au, 74.8 wt % Sn, 2.6 wt % Ag, and 3.0 wt % Cu.

FIG. 11(h) is a surface image of comparative example 4 during RTA treatment.

In comparative example 4, the melting point was 210° C., so the “Melting point” column was “Δ”; no voids occurred after the RTA treatment, so the “Voids” column was “O”; the molten state continued for less than 1 second, so the “Melting duration” column was “X.” Since the “Melting point” column was “Δ,” the “Voids” column was “O,” and the “Melting duration” column was “X,” the score of comparative example 4 was 3 points.

Comparative example 5 was formed by sequentially laminating Cu, Ag, Sn, and Au. Comparative example 5 contains 24.5 wt % Au, 70.2 wt % Sn, 2.5 wt % Ag, and 2.8 wt % Cu.

FIG. 11(i) is a surface image of comparative example 5 during RTA treatment.

In comparative example 5, the melting point was higher than 210° C., so the “Melting point” column was “X”; no voids occurred after the RTA treatment, so the “Voids” column was “O”; the molten state continued for less than 1 second, so the “Melting duration” column was “X.” Since the “Melting point” column was “X,” the “Voids” column was “O,” and the “Melting duration” column was “X,” the score of comparative example 5 was 2 points.

Comparative example 6 was formed by sequentially laminating Cu, Ag, Sn, and Au. Comparative example 6 contains 6.9 wt % Au, 79.0 wt % Sn, 4.5 wt % Ag, and 9.6 wt % Cu.

FIG. 11(h) is a surface image of comparative example 6 during RTA treatment.

In comparative example 6, the melting point was 210° C., so the “Melting point” column was “Δ”; a few voids occurred after the RTA treatment, so the “Voids” column was “Δ”; the molten state continued for about 15 seconds or more, so the “Melting duration” column was “O.” Since the “Melting point” column was “Δ,” the “Voids” column was “Δ,” and the “Melting duration” column was “O,” the score of comparative example 6 was 4 points.

The scores of examples 1, 6, 8, and 9 were 5 points, and those of examples 2-5 and 7 were 6 points. In contrast, the scores of comparative examples 1˜4 were 3 points, and those of comparative examples 5 and 6 were 2 points and 4 points, respectively.

Examples 1-9 received a score of 5 points or more, and are usable as a solder layer. The composition range including examples 1-9 is a range in which 7.2-14.0 wt % Au, 0.1-4.4 wt % Ag, and 0.1-10.1 wt % Cu are contained with the remainder except unavoidable impurities being Sn. A solder layer containing 7.2-14.0 wt % Au, 0.1-4.4 wt % Ag, and 0.1-10.1 wt % Cu with the remainder except unavoidable impurities being Sn can be used as the solder layer of the present application.

Examples 1-5 and 7 received a perfect score of 6 points, and are the most suitable as a solder layer. The composition range including examples 1-5 and 7 is a range in which 7.3-7.7 wt % Au, 0.1-3.1 wt % Ag, and 0.5-6.7 wt % Cu are contained with the remainder except unavoidable impurities being Sn. A solder layer containing 7.3-7.7 wt % Au, 0.1-3.1 wt % Ag, and 0.5-6.7 wt % Cu with the remainder except unavoidable impurities being Sn is the most suitable as the solder layer of the present application.

The melting points of examples 1-9 containing 7.2-14.0 wt % Au are 210° C. The solder layer can have a low melting point by containing 7.2-14.0 wt % Au. The melting points of examples 1-8 containing 7.3-14.0 wt % Au are 205° C. The solder layer can have a lower melting point by containing 7.3-14.0 wt % Au. The melting duration of examples 2-5, 7, and 8 containing 7.3-7.7 wt % Au is 15 seconds or more. The melting duration of the solder layer can be extended to 15 seconds or more by containing 7.3-7.7 wt % Au.

The melting points of examples 1-8 containing 0.1-4.4 wt % Ag and 0.1-6.7 wt % Cu are 205° C. The solder layer can have a low melting point by containing 0.1-4.4 wt % Ag and 0.1-6.7 wt % Cu. The melting points of examples 1-7 containing 0.1-3.1 wt % Ag and 0.1-6.7 wt % Cu are 205° C., and no voids occur in examples 1-7. The solder layer can have a low melting point and achieve high reliability without voids by containing 0.1-3.1 wt % Ag and 0.1-6.7 wt % Cu.

In examples 1-9 containing 0.1-10.1 wt % Cu, not many voids occur. The solder layer can achieve high reliability by containing 0.1-10.1 wt % Cu. In examples 1-7 and 9 containing 0.1-10.1 wt % Cu and 0.1-3.1 wt % Ag, no voids occur. The solder layer can achieve higher reliability by containing 0.1-10.1 wt % Cu and 0.1-3.1 wt % Ag.

1. A thin film for semiconductor laser bonding comprising a solder layer that contains 7.2-14.0 wt % Au, 0.1-4.4 wt % Ag, and 0.1-10.1 wt % Cu with the remainder except unavoidable impurities being Sn.

2. The thin film for semiconductor laser bonding according to claim 1, wherein a Cu layer made of Cu is disposed all over one surface of the solder layer.

3. The thin film for semiconductor laser bonding according to claim 1, wherein the thin film contains 7.3-14.0 wt % Au.

4. The thin film for semiconductor laser bonding according to claim 1, wherein the thin film contains 0.1-4.4 wt % Ag and 0.1-6.7 wt % Cu.

5. The thin film for semiconductor laser bonding according to claim 1, wherein the thin film contains 0.1-10.1 wt % Cu and 0.1-3.1 wt % Ag.

6. The thin film for semiconductor laser bonding according to claim 1, wherein the solder layer contains 7.3-7.7 wt % Au, 2.9-3.1 wt % Ag, and 0.5-6.7 wt % Cu.

7. The thin film for semiconductor laser bonding according to claim 1, further comprising a diffusion prevention layer containing Pt and disposed so as to face a surface of the solder layer on which the Cu is disposed.

8. The thin film for semiconductor laser bonding according to claim 7, wherein the diffusion prevention layer comprises a Cr layer containing Cr and a Pt layer that contains Pt and that is disposed between the Cr layer and the solder layer.

9. A method for producing a thin film for semiconductor laser bonding comprising a solder layer that contains 7.2-14.0 wt % Au, 0.1-4.4 wt % Ag, and 0.1-10.1 wt % Cu with the remainder except unavoidable impurities being Sn, the method comprising:
forming a Cu layer;
forming an Ag layer on the Cu layer;
forming an Sn layer on the Ag layer; and
forming an Au layer on the Sn layer.
